(19) United States
(12) Patent Application Publication
(10) Pub. No.: US 2015/0248062 A1
(43) Pub. Date: Sep. 3, 2015

(54) DIGITAL EXPOSURE METHOD AND DIGITAL EXPOSURE APPARATUS FOR PERFORMING THE SAME

(71) Applicant: SAMSUNG DISPLAY CO., LTD., YONGIN-CITY (KR)

(72) Inventors: SANG-HYUN YUN, SUWON-SI (KR); HYUN-SEOK KIM, HWASEONG-SI (KR); HI-KUK LEE, YONGIN-SI (KR); JUNG-IN PARK, SOUL (KR); JAE-HYUK CHANG, SEONGNAM-SI (KR); CHANG-HOON KIM, ASAN-SI (KR); KI-BEOM LEE, SEOUL (KR)

(21) Appl. No.: 14/459,912

(22) Filed: Aug. 14, 2014

(30) Foreign Application Priority Data
Mar. 3, 2014 (KR) 10-2014-0024879

(51) Int. Cl. G03F 7/20

(52) U.S. Cl. CPC G03F 7/70058

(57) ABSTRACT

A method for digitally exposing a substrate includes generating first horizontal pattern area graphic data and second horizontal pattern area graphic data, where the first horizontal pattern area graphic data corresponds to a first pattern, and the second horizontal pattern area graphic data corresponds to a second pattern, generating a second light incident into the substrate by changing a light path of a first light based on the first horizontal pattern area graphic data and the second horizontal pattern area graphic data, and forming a first pattern on the substrate from the first horizontal pattern area graphic data and a second pattern on the substrate spaced apart in a first direction from the first pattern from the second horizontal pattern area graphic data by exposing the substrate with the second light in a second direction perpendicular to the first direction in a plan view.

This application claims priority under 35 U.S.C. 119 from Korean Patent Application No. 10-2014-0024879, filed on Mar. 3, 2014 in the Korean Intellectual Property Office, and all the benefits accruing therefrom, the contents of which are herein incorporated by reference in their entirety.

### BACKGROUND

1. Technical Field

Exemplary embodiments of the inventive concept are directed to a digital exposure method and a digital exposure apparatus for performing the digital exposure method. More particularly, exemplary embodiments of the inventive concept are directed to a digital exposure method capable of improving an accuracy of a pattern and a digital exposure apparatus for performing the digital exposure method.

2. Discussion of the Related Art

In general, to form a metal pattern that includes signal lines and a thin film transistor (“TFT”) that is a switching element of a display substrate, a metal layer and a photoresist layer are sequentially formed, and a mask corresponding to the metal pattern is disposed on the photoresist layer.

Then, light is irradiated upon the photoresist layer through the mask to expose the photoresist layer, and the photoresist layer is developed. Thus, a photoresist pattern corresponding to the mask may be formed. The metal layer may be etched to form the metal pattern. When the metal layer is etched, the photoresist pattern functions as an etch stop layer.

When a display substrate includes a plurality of differently shaped metal patterns, a plurality of masks corresponding to the number of the metal patterns is required. In addition, if the shapes of the metal patterns change, the shape of the mask should change correspondingly so that a new mask may be needed. Since the fabrication cost of a mask is relatively high, the manufacturing cost of the display substrate may increase.

Alternatively, a digital exposure apparatus may be used to provide a plurality of beams to a substrate without the mask. In a digital exposure apparatus, beams may be independently and selectively provided to the substrate. Thus, a desired photoresist pattern may be formed on the substrate.

The area on which the light from the digital exposure apparatus is incident is quite limited, so that either the digital exposure apparatus or the substrate needs to be displaced to form a photoresist pattern on a large-size substrate.

However, when the substrate is scanned by the digital exposure apparatus, an overlap area may be generated. In this approach, the overlap area of the substrate can be exposed by the digital exposure apparatus two or more times so that an amount of exposure of the overlap area may differ from an amount of exposure of an area which is exposed once by the digital exposure apparatus. Thus, a uniformity of the photoresist pattern may be decreased

### SUMMARY

One or more exemplary embodiments of the inventive concept provide a digital exposure method capable of improving an accuracy of a pattern.

One or more exemplary embodiments of the inventive concept also provide a digital exposure apparatus for performing the digital exposure method.

According to an exemplary embodiment, a method for exposing a substrate includes generating a second light incident into the substrate by changing a light path of a first light based on a first horizontal pattern area graphic data and a second horizontal pattern area graphic data, and forming a first pattern on the substrate from the first horizontal pattern area graphic data and a second pattern on the substrate spaced apart in a first direction from the first pattern from the second horizontal pattern area graphic data by exposing the substrate with the second light in a second direction perpendicular to the first direction in a plan view.

In an exemplary embodiment, the first pattern may be formed in a first horizontal exposure area of the substrate and the second pattern may be formed in a second horizontal exposure area adjacent to the first horizontal exposure area in the first direction. The light path of the first light may be changed by a digital micro mirror part configured to expose the first horizontal exposure area based on the first horizontal pattern area graphic data, and to expose the second horizontal exposure area based on the second horizontal pattern area graphic data. A border between the first horizontal exposure area and the second horizontal exposure area may be spaced apart from the first pattern and the second pattern.

In an exemplary embodiment, the digital micro mirror part may include a first digital micro mirror device and a second digital micro mirror device spaced apart from the first digital micro mirror device. The first and second digital micro mirror devices may be configured to generate a plurality of light paths for the second light, respectively. Exposing the substrate with the second light may include exposing the first horizontal exposure area with the first digital micro mirror device, and exposing the second horizontal exposure area with the second digital micro mirror device.

In an exemplary embodiment, the method may include generating on/off data for the first digital micro mirror device based on the first horizontal pattern area graphic data, and generating on/off data for the second digital micro mirror device based on the second horizontal pattern area graphic data.

In an exemplary embodiment, the first digital micro mirror device and the second digital micro mirror device may expose the substrate simultaneously.

In an exemplary embodiment, the second horizontal exposure area may partially overlap the first horizontal exposure area.

In an exemplary embodiment, the method may include generating the first horizontal pattern area graphic data and the second horizontal pattern area graphic data by dividing a graphic data corresponding to a first pattern array that includes the first pattern and the second pattern.

In an exemplary embodiment, the graphic data may be divided based on a pixel unit.

In an exemplary embodiment, the method further includes generating a first vertical pattern area graphic data and a second vertical pattern area graphic data, where the first vertical pattern area graphic data corresponds to a third pattern, and the second vertical pattern area graphic data corresponds to a fourth pattern spaced apart from the third pattern in the second direction, generating the second light incident into the substrate by changing the light path of the first light based on the first vertical pattern area graphic data and the second vertical pattern area graphic data, and forming a second pattern array on the substrate that includes the third and fourth patterns spaced apart in the second direction by exposing the substrate with the second light sequentially in the first direction.

In an exemplary embodiment, generating the first vertical pattern area graphic data and the second vertical pattern area graphic data may include dividing a graphic data corresponding to the second pattern array.

According to an exemplary embodiment, a digital exposure apparatus includes a stage and an exposure part. The stage is configured to receive a substrate. The exposure part is configured to generate a second light that includes plural light paths based on a first pattern area graphic data corresponding to a first pattern and a second pattern area graphic data corresponding to a second pattern spaced apart from the first pattern in a first direction in a plan view, and to use the second light to expose a first exposure area of the substrate based on the first pattern area graphic data and a second exposure area of the substrate based on the second pattern area graphic data in a second direction perpendicular to the first direction.

In an exemplary embodiment, the exposure part may include a light source part configured to generate a first light, and a first digital micro mirror device that includes a plurality of digital micro mirrors configured to convert the first light into the second light.

In an exemplary embodiment, a border between the first exposure area and the second exposure area may be spaced apart from patterns of the first pattern area graphic data and patterns of the second pattern area graphic data.

In an exemplary embodiment, the second exposure area may partially overlap the first exposure area.

In an exemplary embodiment, the exposure part may further include a second digital micro mirror device spaced apart from the first digital micro mirror device that includes a plurality of digital micro mirrors configured to convert the first light into the second light.

In an exemplary embodiment, the first digital micro mirror device may be configured to expose the first exposure area. The second digital micro mirror device may be configured to expose the second exposure area.

In an exemplary embodiment, the first pattern area graphic data and the second pattern area graphic data may be generated by dividing a graphic data corresponding to a first pattern array including the first and second patterns.

In an exemplary embodiment, the graphic data may be divided based on a pixel unit.

According to an exemplary embodiment, a method for digitally exposing a substrate includes generating a first horizontal pattern area graphic data and a second horizontal pattern area graphic data, wherein the first horizontal pattern area graphic data corresponds to a first pattern, and the second horizontal pattern area graphic data corresponds to a second pattern; and forming the first pattern in a first horizontal exposure area of the substrate from the first horizontal pattern area graphic data and the second pattern in a second horizontal exposure area of the substrate spaced apart in a first direction from the first pattern from the second horizontal pattern area graphic data by exposing the substrate to a second light in a second direction perpendicular to the first direction in a plan view.

In an exemplary embodiment, the method may include generating the second light by changing a light path of a first light based on the first horizontal pattern area graphic data and the second horizontal pattern area graphic data. The light path of the first light may be changed by a digital micro mirror part configured to expose the first horizontal exposure area based on the first horizontal pattern area graphic data, and to expose the second horizontal exposure area based on the second horizontal pattern area graphic data. The digital micro mirror part may include a first digital micro mirror device and a second digital micro mirror device spaced apart from the first digital micro mirror device. The first horizontal exposure area may be exposed with the first digital micro mirror device, and the second horizontal exposure area may be exposed with the second digital micro mirror device.

According to one or more exemplary embodiment of the digital exposure method and the digital exposure apparatus for performing the digital exposure method, an accuracy of a pattern may be improved. In addition, a display quality of a display apparatus manufactured by the digital exposure apparatus may be improved.

### BRIEF DESCRIPTION OF THE DRAWINGS

FIG. 1 is a plan view that illustrates a digital exposure apparatus according to an exemplary embodiment of the inventive concept.

FIG. 2 is a cross-sectional view that illustrates the digital exposure apparatus of FIG. 1.

FIG. 3 is a plan view that illustrates a digital micro mirror part of FIG. 2.

FIG. 4 is a conceptual diagram that illustrates an exposure area exposed by the digital exposure apparatus of FIG. 1.

FIG. 5 is a conceptual diagram that illustrates a method of dividing graphic data corresponding to a first pattern array.

FIG. 6 is an enlarged plan view that illustrates a pattern corresponding to a portion ‘A’ of FIG. 5.

FIG. 7 is a plan view that illustrates a moving direction of a substrate in a step of exposing a second pattern array.

FIG. 8 is a conceptual diagram that illustrates a method of dividing a graphic data corresponding to the second pattern array.

FIG. 9 is an enlarged plan view that illustrates a pattern corresponding to a portion ‘B’ of FIG. 8.

### DETAILED DESCRIPTION

Hereinafter, embodiments of the inventive concept will be explained in detail with reference to the accompanying drawings.

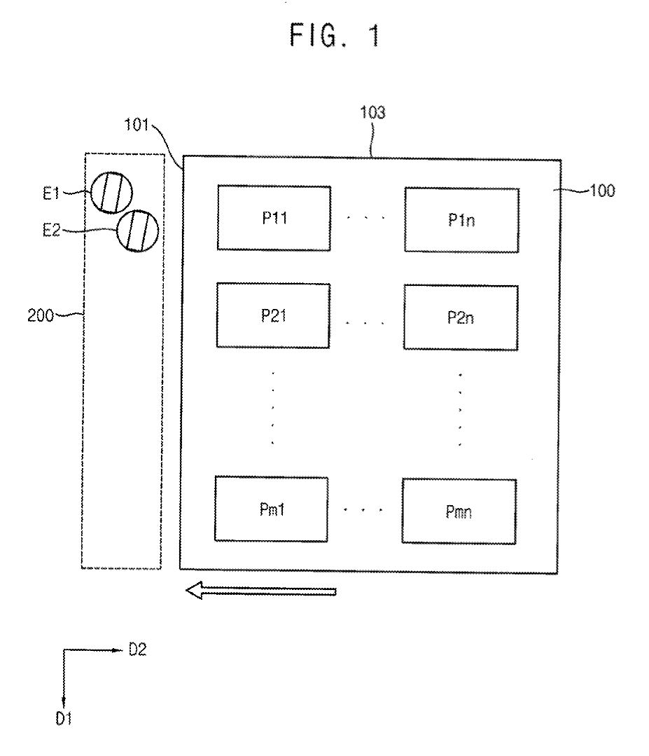

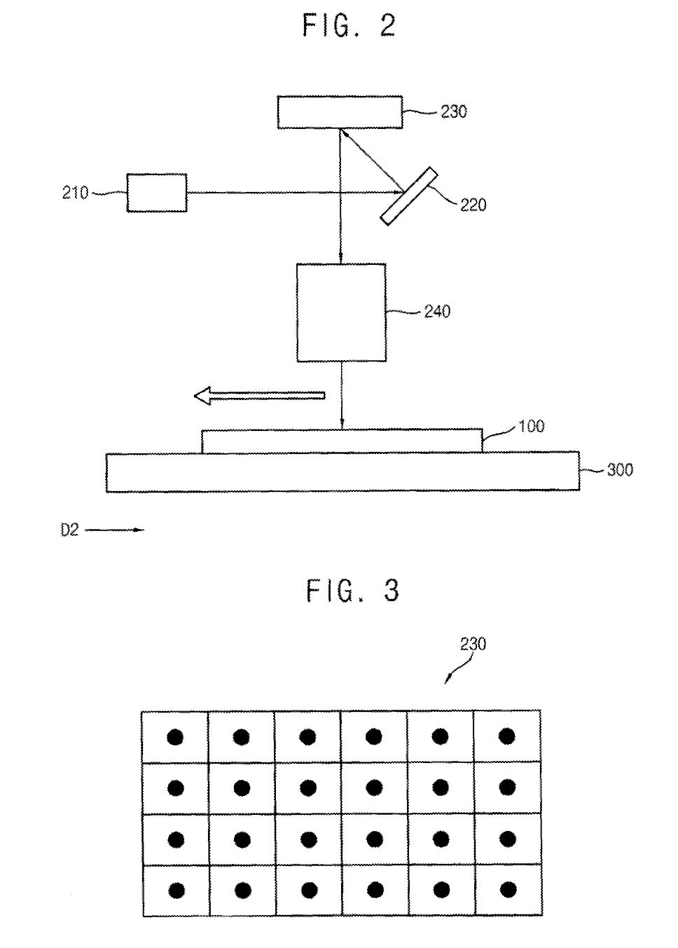

FIG. 1 is a plan view that illustrates a digital exposure apparatus according to an exemplary embodiment of the inventive concept. FIG. 2 is a cross-sectional view that illustrates the digital exposure apparatus of FIG. 1.

Referring to FIGS. 1 and 2, the digital exposure apparatus includes an exposure part 200 and a stage 300 for displacing a substrate 100.

The substrate 100 may be a mother substrate for forming a plurality of display panels. The substrate 100 may include a plurality of panel areas P11, P21, . . . , Pmn arranged in a first direction D1 and a second direction D2 perpendicular to the first direction. The panel areas P11, P21, . . . , Pmn may be arranged in a matrix pattern. Herein, m and n are positive integers.

The substrate 100 may be displaced along a third direction opposite to the second direction. The substrate 100 may be transferred to the exposure part 200 by the stage 300 under the substrate 100. For example, the substrate 100 may include a first edge 101 parallel to the first direction of the substrate 100, and the first edge 101 may face the exposure part 200 when the substrate is transferred to the exposure part 200. The substrate 100 may also include a second edge 103 parallel to the second direction, and the second edge 103 may alternatively face the exposure part 200 when the substrate 100 is transferred to the exposure part 200.

A photosensitive film may be disposed on the substrate 100. The photosensitive film may be used to form a mask for forming a pattern on the substrate 100. The photosensitive film may include a photosensitive resin such as a photosensitive epoxy resin coated on a surface of the substrate 100.

The substrate 100 may be exposed by a step type exposure or a scan type exposure. In a step type exposure, the stage 300 may discontinuously displace the substrate 100 with repetitive discrete displacements. In a scan type exposure, the stage 300 may continuously displace the substrate 100. When an island pattern is formed on the substrate 100, a step type exposure may be used. When a strip pattern is formed on the substrate 100, a scan type exposure may be used.

The exposure part 200 may include a plurality of exposure heads E1, E2, . . . . For clarity, only two exposure heads E1, E2, are illustrated, however, the exposure part is not limited thereto, and may contain an arbitrary number of exposure heads. The exposure heads E1, E2, . . . , are disposed along the first direction D1 substantially perpendicular to the third direction.

For example, the exposure heads E1 and E2 may be disposed in two columns. The exposure heads disposed in a first column alternate with the exposure heads disposed in a second column. Alternatively, the exposure heads disposed in the first column may overlap with the exposure heads disposed in the second column. These arrangements are exemplary and not limited thereto. Although not shown in figures, the exposure heads E1 and E2 may be disposed in various other arrangements along the first direction D1.

The exposure part 200 exposes the substrate 100 being displaced in the third direction, so that an exposure pattern is formed on the substrate 100 along the second direction D2 opposite to the third direction.

Referring to FIG. 2, each of the exposure heads includes a light source part 210, a mirror 220, a digital micro mirror part 230 and a projection optical device 240.

The light source part 210 generates a first light and emits the first light to the mirror 220. The light source part 210 may continuously generate and emit the first light. The light source part 210 may include a light generating part, a light diffusing part, a filtering part and a collimator. The first light may be ultraviolet light which causes a reaction in the photosensitive film.

The mirror 220 changes the direction of the first light, so that the first light propagates to the digital micro mirror part 230. The mirror 220 is inclined with respect to the propagation direction of the first light.

The digital micro mirror part 230 receives the first light from the mirror 220. The digital micro mirror part 230 converts the first light into a second light that includes a plurality of light paths, and emits the second light. The digital micro mirror part 230 may emit the second light in a direction substantially perpendicular to the substrate 100.

The digital micro mirror part 230 may include a micro electro mechanical system (“MEMS”) type digital micro mirror device (“DMD”).

The digital micro mirror part 230 may include a plurality of digital micro mirrors. The shape and operation of the digital micro mirror part 230 will be explained in detail with reference to FIG. 3.

The projection optical device 240 may include a plurality of lenses. The projection optical device 240 may convert the second light emitted by the digital micro mirror part 230 into a plurality of exposure beams and emits the exposure beams to the substrate 100.

FIG. 3 is a plan view that illustrates a digital micro mirror part of FIG. 2.

Referring to FIGS. 1 to 3, the digital micro mirror part 230 includes a plurality of the digital micro mirrors. The digital micro mirrors convert the first light into the second light having a plurality of light paths.

The digital micro mirrors are disposed in a matrix configuration. For clarity, FIG. 3 illustrates a 4×6 array of digital micro mirrors. However, the number of the digital micro mirrors is not limited to that shown in FIG. 3, and may be greater than or less than the number shown in FIG. 3.

Each of the digital micro mirrors may have a rectangular shape. For example, each of the digital micro mirrors may have a square shape.

The digital micro mirror part 230 may selectively convert the first light into the second light based on graphic data corresponding to a desired pattern.

The digital micro mirror part 230 is connected to a digital micro mirror controller. The digital micro mirror controller respectively outputs control signals for controlling on/off states of the digital micro mirrors to the digital micro mirrors based on the graphic data.

When the control signal of an individual digital micro mirror indicates an on state, the digital micro mirror may convert the first light into the second light and emit the second light to the substrate 100.

When the control signal of an individual digital micro mirror indicates an off state, the digital micro mirror may not convert the first light into the second light and may not emit the second light to the substrate 100.

The number of light paths of the second light may be less than or equal to the number of the digital micro mirrors. For example, when each of the digital micro mirrors has an on state, the number of light paths of the second light is equal to the number of the digital micro mirrors.

An angle of the digital micro mirror may be adjusted in accordance with the control signal of the digital micro mirror. For example, when a digital micro mirror has an on state, the digital micro mirror may be inclined by +12 degrees with respect to a reference angle. When a digital micro mirror has an off state, the digital micro mirror may be inclined by −12 degrees with respect to the reference angle.

The digital micro mirror controller may be connected to a central portion of each of the digital micro mirrors.

Each of the exposure beams emitted to the substrate 100 by the digital micro mirror part 230 and the projection optical device 240 forms a dot. The exposure beams are discontinuously distributed on the substrate 100 with gaps separating the exposure beams. Thus, the substrate 100 is partially exposed by the exposure beams.

The digital micro mirror part 230 may be inclined with respect to the substrate 100. By changing the inclination of the digital micro mirror part 230 with respect to the substrate 100, gaps between the exposure beams irradiated to the substrate 100 may be adjusted. Thus, a line pattern or a plane pattern may be formed using the digital exposure apparatus.

Hereinafter, the substrate 100 will be represented by the first panel area P11 as shown in FIG. 1, and the first panel area P11 may be applied equally to other panel areas.

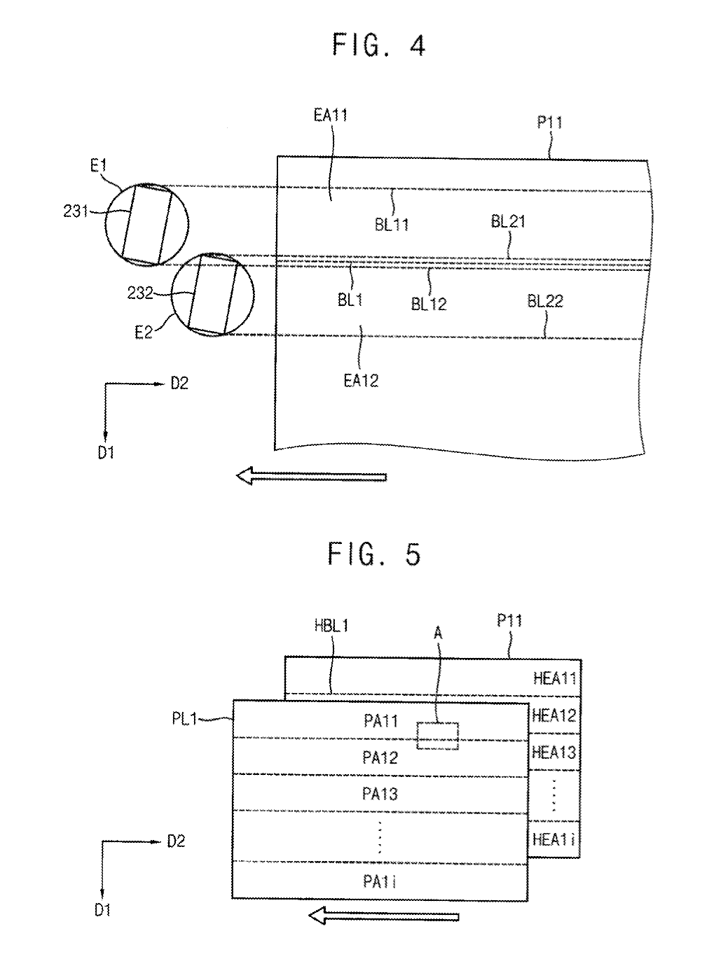

FIG. 4 is a conceptual diagram that illustrates an exposure area exposed by the digital exposure apparatus of FIG. 1.

Referring to FIGS. 1 and 4, the first exposure head E1 may expose a first exposure area EA11 of the first panel area P11. The second exposure head E2 adjacent to the first exposure head E1 may expose a second exposure area EA12 of the first panel area P11.

The first exposure head E1 may include a first digital micro mirror device 231. An area between a first upper boundary line BL11 and a first lower boundary line BL12 may be covered by the first digital micro mirror device 231.

The second exposure head E2 may include a second digital micro mirror device 232. An area between a second upper boundary line BL21 and a second lower boundary line BL22 may be covered by the second digital micro mirror device 232.

The area covered by the first exposure head E1 may partially overlap with the area covered by the second exposure head E2. A first boundary line BL1 may be defined by a center line of the overlap area covered by the first and second exposure heads E1 and E2. The first boundary line BL1 may be a substantially straight line. Alternatively, the first boundary line BL1 may be a polygonal line corresponding to a shape of a nearby pattern.

The first exposure head E1 may expose an area between the first upper boundary line BL11 and the first boundary line BL1. The second exposure head E2 may expose an area between the first boundary line BL1 and the second lower boundary line BL22. Thus, the first exposure area EAU and the second exposure area EA12 may not overlap each other.

Alternatively, the first exposure head E1 may expose an area between the first upper boundary line BL11 and the first lower boundary line BL12. The second exposure head E2 may expose an area between the second upper boundary line BL21 and the second lower boundary line BL22. Thus, the first exposure area EAU and the second exposure area EA12 may partially overlap with each other.

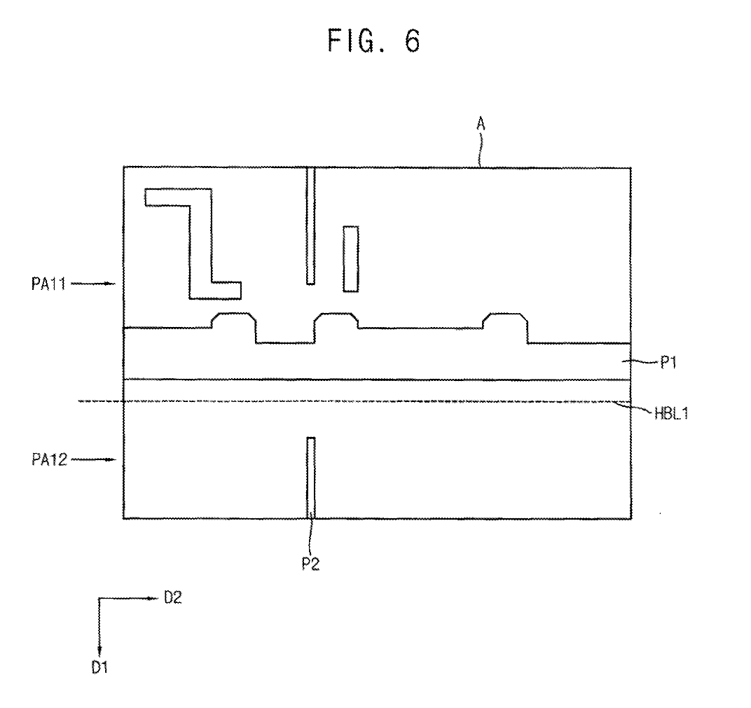

FIG. 5 is a conceptual diagram that illustrates a method of dividing graphic data corresponding to a first pattern array. FIG. 6 is an enlarged plan view that illustrates a pattern corresponding to a portion ‘A’ of FIG. 5.

Referring to FIGS. 1 and 4 to 6, the exposure part 200 may expose the substrate in the second direction D2, creating, e.g., a first pattern array PL1 of the first panel area P11. The substrate 100 may be displaced in the third direction while being exposed by the exposure part 200.

The first pattern array PL1 may include a plurality of first patterns. The first patterns extend in the second direction D2 and are arranged in the first direction D1. The first patterns may be disposed in a same layer. For example, the first pattern array PL1 may be a gate pattern layer, but is not limited thereto, and the first pattern array PL1 may include a plurality of patterns that extend in the second direction D2 and are arranged in the first direction D1.

The first pattern array PL1 may be divided into a plurality of horizontal pattern areas PA11, PA12, PA13, . . . , PA1i that extend in the second direction D2 and are arranged in the first direction D1. Herein, ‘i’ is a positive integer.

The first pattern array PL1 may be divided into first to i-th horizontal pattern areas PA11, PA12, PA13, . . . , PA1i based on a pixel unit. For example, the first pattern array PL1 may include a plurality of pixel areas that correspond to each pixel, and each of the first to i-th horizontal pattern areas PA11, PA12, PA13, . . . , PA1i may include at least one pixel area, respectively. Alternatively, the first pattern array PL1 may be divided based on a reference unit which is smaller than the pixel unit.

Referring to FIGS. 4 and 5, the first panel area P11 may be divided into a plurality of horizontal exposure areas HEA11, HEA12, HEA13, . . . , HEA1i that extend in the second direction D2 and are arranged in the first direction D1.

Referring to FIG. 6, patterns included in the horizontal pattern areas PA11, PA12, PA13, . . . , PA1i may be spaced apart from each other in the first direction D1. For example, patterns P2, which are included in the second horizontal pattern area PA12, are spaced apart, in the first direction D1 from patterns P1, which are included in the first horizontal pattern area PA11. A first horizontal boundary HBL1 is a boundary between a first horizontal exposure area HEA11 and a second horizontal exposure area HEA12. The first horizontal exposure area HEA11 may be exposed by the first exposure head E1. The second horizontal exposure area HEA12 may be exposed by the second exposure head E2. The first horizontal boundary HBL1 may be disposed between the patterns P1 and the patterns P2.

For example, no pattern of the first horizontal pattern area PA11 may be connected to a pattern of the second horizontal patterns area PA12.

The first to i-th horizontal exposure areas HEA11, HEA12, HEA13, . . . , HEA1i may correspond to the first to i-th horizontal pattern areas PA11, PA12, PA13, . . . , PA1i, respectively. For example, the first horizontal exposure area HEA11 may correspond to the first horizontal pattern area PA11, and the second horizontal exposure area HEA12 may correspond to the second horizontal pattern area PA12.

Thus, horizontal boundaries between the first to i-th horizontal exposure areas HEA11, HEA12, HEA13, . . . , HEA1i may correspond to boundaries between the first to i-th horizontal pattern areas PA11, PA12, PA13, . . . , PA1i, respectively.

The digital micro mirror controller may receive first graphic data that includes graphic data of the first pattern array PL1. For example, the digital micro mirror controller may receive the first graphic data divided into first to i-th horizontal pattern area graphic data corresponding to the first to i-th horizontal pattern areas PA11, PA12, PA13, . . . , PA1i. The first to i-th horizontal pattern area graphic data may correspond to the first to i-th horizontal pattern areas PA11, PA12, PA13, . . . , PA1i, respectively.

Thus, patterns corresponding to the horizontal pattern area graphic data may be spaced apart in the first direction D1 from patterns corresponding to the adjacent horizontal pattern area graphic data. For example, the patterns P2 corresponding to the second horizontal pattern area graphic data may be spaced apart in the first direction D1 from patterns P1 corresponding to the first horizontal pattern area graphic data. Thus, the patterns of the first horizontal pattern area graphic data may not be connected to the patterns of the second horizontal patterns area graphic data.

The first graphic data may be divided into the first to i-th horizontal pattern area graphic data based on the pixel unit, in accordance with the division of the first pattern array PL1. For example, each of the first to i-th horizontal pattern area graphic data may include at least one graphic data of a pixel unit. Alternatively, the first graphic data may be divided based on a reference unit which is smaller than the pixel unit.

A first digital micro mirror controller of the first exposure head E1 may receive the first horizontal pattern area graphic data. The first digital micro mirror controller may generate on/off data for the first digital micro mirror device 231 based on the first horizontal pattern area graphic data, and may control the first digital micro mirror device 231. The first digital micro mirror device 231 may expose the first horizontal exposure area HEA11.

A second digital micro mirror controller of the second exposure head E2 may receive the second horizontal pattern area graphic data. The second digital micro mirror controller may generate on/off data for the second digital micro mirror device 232 based on the second horizontal pattern area graphic data, and may control the second digital micro mirror device 232. The second digital micro mirror device 232 may expose the second horizontal exposure area HEA12. The second digital micro mirror device 232 may expose the second horizontal exposure area HEA12, when the first digital micro mirror device 231 exposes the first horizontal exposure area HEA11. The first digital micro mirror device 231 and the second digital micro mirror device 232 may expose the first horizontal exposure area HEA11 and the second horizontal exposure area HEA12 during a first period, and then sequentially expose remaining horizontal exposure areas two at a time. Alternatively, the exposure part 200 may include a plurality of the digital micro mirror devices that correspond to the number of the horizontal exposure areas, and the first panel area P11 may be simultaneously exposed by the digital micro mirror devices.

Alternatively, during a first period, the first exposure head E1 may expose the first horizontal exposure area HEA11 based on the first horizontal pattern area graphic data. During a second period, the first exposure head E1 may expose the second horizontal exposure area HEA12 based on the second horizontal pattern area graphic data. The first exposure head E1 may move to a position of the second exposure head E2 during a period between the first period and the second period.

In an exemplary embodiment, the exposure part 200 includes the first and second exposure heads E1 and E2, but the number of the exposure heads is not limited thereto.

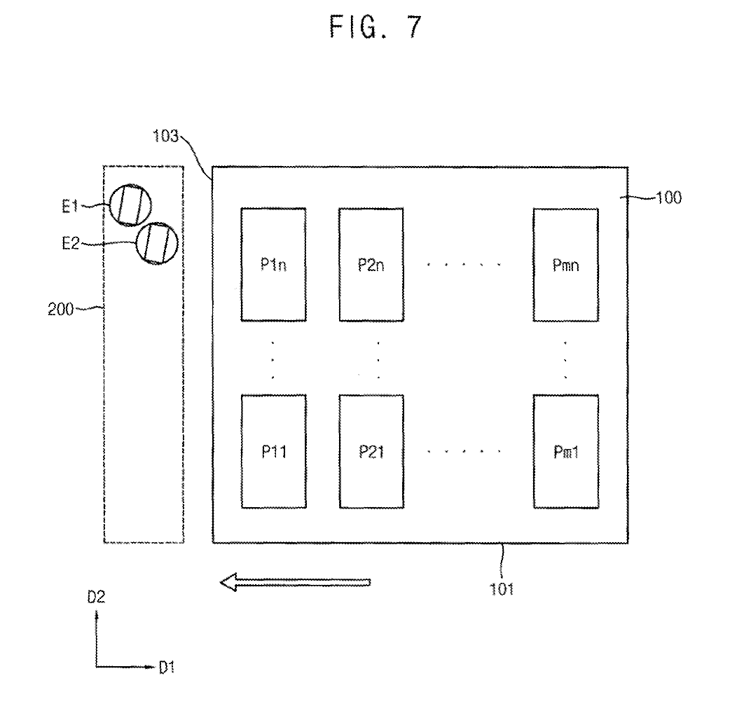

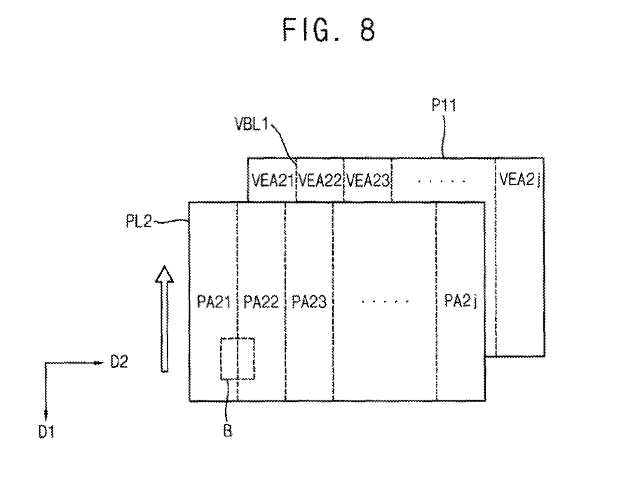

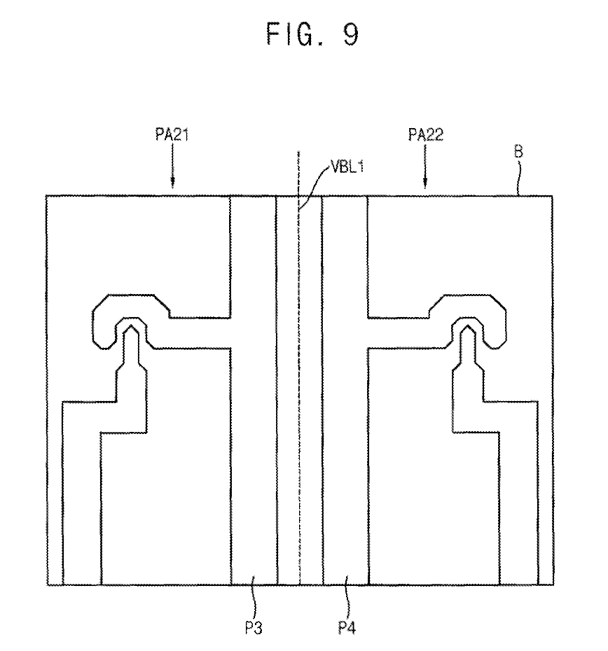

FIG. 7 is a plan view that illustrates a moving direction of a substrate in a step of exposing a second pattern array. FIG. 8 is a conceptual diagram that illustrates a method of dividing a graphic data corresponding to the second pattern array. FIG. 9 is an enlarged plan view that illustrates a pattern corresponding to a portion ‘13’ of FIG. 8.

Referring to FIGS. 1, 4 and 7 to 9, the exposure part 200 may expose the substrate in the first direction D1, creating, e.g., a second pattern array PL2 of the first panel area P11. The substrate 100 may be displaced in the fourth direction opposite to the first direction D1 while being exposed by the exposure part 200.

The substrate 100 and the exposure part 200 may be rearranged to expose the substrate in the first direction D1.

The second pattern array PL2 may include a plurality of second patterns. The second patterns extend in the first direction D1 and are arranged in the second direction D2. The second patterns may be disposed in a same layer. For example, the second pattern array PL2 may be a data pattern layer, but is not limited thereto, and the second pattern array PL2 may include a plurality of patterns extending in the first direction D1 and arranged in the second direction D2.

The second pattern array PL2 may be divided into a plurality of vertical pattern areas PA21, PA22, PA23, . . . , PA2j that extend in the first direction D1 and are arranged in the second direction D2. Herein, ‘J’ is a positive integer.

The second pattern array PL2 may be divided into first to j-th vertical pattern areas PA21, PA22, PA23, . . . , PA2j based on a pixel unit. For example, the second pattern array PL2 may include a plurality of pixel areas that correspond to each pixel, and each of the first to j-th vertical pattern areas PA21, PA22, PA23, . . . , PA2j may include at least one pixel area, respectively. Alternatively, the second pattern array PL2 may be divided based on a reference unit smaller than the pixel unit.

Referring back to FIGS. 4 and 8, the first panel area P11 may be divided into a plurality of vertical exposure areas VEA21, VEA22, VEA23, . . . , VEA2j that extend in the first direction D1 and are arranged in the second direction D2.

Referring to FIG. 9, patterns included in the vertical pattern areas PA21, PA22, PA23, . . . , PA2j may be spaced apart from each other in the second direction D2. For example, patterns P4, which are included in the second vertical pattern area PA22, are spaced apart in the second direction D2 from patterns P3, which are included in the first vertical pattern area PA21. A first vertical boundary VBL1 is a boundary between a first vertical exposure area VEA21 and a second vertical exposure area VEA22. The first vertical exposure area VEA21 may be exposed by the first exposure head E1. The second vertical exposure area VEA22 may be exposed by the second exposure head E2. The first vertical boundary VBL1 may be disposed between the patterns P3 and the patterns P4.

For example, no pattern of the first vertical pattern area PA21 may be connected to a pattern of the second vertical patterns area PA22.

The first to j-th vertical exposure areas VEA21, VEA22, VEA23, . . . , VEA2j may correspond to the first to j-th vertical pattern areas PA21, PA22, PA23, . . . , PA2j, respectively. For example, the first vertical exposure area VEA21 may correspond to the first vertical pattern area PA22, and the second vertical exposure area VEA22 may correspond to the second vertical pattern area PA22.

Thus, vertical boundaries between the first to j-th vertical exposure areas VEA21, VEA22, VEA23, . . . , VEA2j may correspond to boundaries between the first to j-th vertical pattern areas PA21, PA22, PA23, . . . , PA2j, respectively.

The digital micro mirror controller may receive second graphic data that includes graphic data of the second pattern array PL2. For example, the digital micro mirror controller may receive the second graphic data divided into first to j-th vertical pattern area graphic data corresponding to the first to j-th vertical pattern areas PA21, PA22, PA23, . . . , PA2j. The first to j-th vertical pattern area graphic data may correspond to the first to j-th vertical pattern areas PA21, PA22, PA23, . . . , PA2j, respectively.

Thus, patterns corresponding to the vertical pattern area graphic data may be spaced apart in the second direction D2 from patterns corresponding to the adjacent vertical pattern area graphic data. For example, the patterns P4 corresponding to the second vertical pattern area graphic data may be spaced apart in the second direction D2 from patterns P3 corresponding to the first vertical pattern area graphic data. Thus, no pattern of the first vertical pattern area graphic data may be connected to a pattern of the second vertical patterns area graphic data.

The second graphic data may be divided into first to j-th vertical pattern area graphic data based on the pixel unit, in accordance with the division of the second pattern array PL2. For example, each of the first to j-th vertical pattern area graphic data may include graphic data of a pixel unit. Alternatively, the second graphic data may be divided based on a reference unit smaller than the pixel unit.

A first digital micro mirror controller of the first exposure head E1 may receive the first vertical pattern area graphic data. The first digital micro mirror controller may generate on/off data for the first digital micro mirror device 231 based on the first vertical pattern area graphic data, and may control the first digital micro mirror device 231. The first digital micro mirror device 231 may expose the first vertical exposure area VEA21.

A second digital micro mirror controller of the second exposure head E2 may receive the second vertical pattern area graphic data. The second digital micro mirror controller may generate on/off data for the second digital micro mirror device 232 based on the second vertical pattern area graphic data, and may control the second digital micro mirror device 232. The second digital micro mirror device 232 may expose the second vertical exposure area VEA22. The second digital micro mirror device 232 may expose the second vertical exposure area VEA22, when the first digital micro mirror device 231 exposes the first vertical exposure area VEA21.

Alternatively, during a third period, the first exposure head E1 may expose the first vertical exposure area VEA21 based on the first vertical pattern area graphic data. During a fourth period, the first exposure head E1 may expose the second vertical exposure area VEA22 based on the second vertical pattern area graphic data. The first exposure head E1 may move to a position of the second exposure head E2 during a period between the third period and the fourth period.

According to one or more of the illustrated exemplary embodiments, graphic data applied to the first and second exposure heads may be divided to locate a boundary between areas exposed by the first and second exposure heads in an empty area on which patterns are not disposed. Thus, a stitch of patterns disposed on the substrate may decrease, which may improve an accuracy of the pattern. In addition, a display quality of a display apparatus manufactured by the digital exposure apparatus may be improved.

A digital exposure apparatus of the illustrated exemplary embodiments may be applied to an exposure apparatus that manufacture a display panel of a mobile display apparatus such as a mobile phone, a note book computer, a tablet computer, etc., a display panel of a fixed display such as a television, a desktop display, etc., and a display panel for a general appliance such as a refrigerator, a washing machine or an air conditioner.

The foregoing is illustrative of embodiments of the inventive concept and is not to be construed as limiting thereof. Although a few exemplary embodiments of the inventive concept have been described, those skilled in the art will readily appreciate that many modifications are possible in the exemplary embodiments without materially departing from the novel teachings and advantages of the inventive concept. Accordingly, all such modifications are intended to be included within the scope of the inventive concept as defined in the claims. Therefore, it is to be understood that the foregoing is illustrative of the embodiments of the inventive concept and is not to be construed as limited to the specific exemplary embodiments disclosed, and that modifications to the disclosed exemplary embodiments, as well as other exemplary embodiments, are intended to be included within the scope of the appended claims. The inventive concept is defined by the following claims, with equivalents of the claims to be included therein.

What is claimed is:

1. A method for digitally exposing a substrate, comprising the steps of:
generating a second light incident into the substrate by changing a light path of a first light based on a first horizontal pattern area graphic data and a second horizontal pattern area graphic data; and
forming a first pattern on the substrate from the first horizontal pattern area graphic data and a second pattern on the substrate spaced apart in a first direction from the first pattern from the second horizontal pattern area graphic data by exposing the substrate with the second light in a second direction perpendicular to the first direction in a plan view.

2. The method of claim 1, wherein
the first pattern is formed in a first horizontal exposure area of the substrate, and the second pattern is formed in a second horizontal exposure area of the substrate adjacent to the first horizontal exposure area in the first direction,
the light path of the first light is changed by a digital micro mirror part configured to expose the first horizontal exposure area based on the first horizontal pattern area graphic data, and to expose the second horizontal exposure area based on the second horizontal pattern area graphic data, and
a border between the first horizontal exposure area and the second horizontal exposure area is spaced apart from the first pattern and the second pattern.

3. The method of claim 2, wherein
the digital micro mirror part comprises a first digital micro mirror device and a second digital micro mirror device spaced apart from the first digital micro mirror device, wherein the first and second digital micro mirror devices are configured to generate a plurality of light paths for the second light, respectively, and
exposing the substrate with the second light comprises:
exposing the first horizontal exposure area with the first digital micro mirror device; and
exposing the second horizontal exposure area with the second digital micro mirror device.

4. The method of claim 3, further comprising
generating on/off data for the first digital micro mirror device based on the first horizontal pattern area graphic data; and
generating on/off data for the second digital micro mirror device based on the second horizontal pattern area graphic data.

5. The method of claim 3, wherein the first digital micro mirror device and the second digital micro mirror device expose the substrate simultaneously.

6. The method of claim 2, wherein the second horizontal exposure area partially overlaps the first horizontal exposure area.

7. The method of claim 1, further comprising generating the first horizontal pattern area graphic data and the second horizontal pattern area graphic data by dividing a graphic data corresponding to a first pattern array that includes the first pattern and the second pattern.

8. The method of claim 7, wherein the graphic data is divided based on a pixel unit.

9. The method of claim 1, further comprising:
generating a first vertical pattern area graphic data and a second vertical pattern area graphic data, wherein the first vertical pattern area graphic data corresponds to a third pattern, and the second vertical pattern area graphic data corresponds to a fourth pattern spaced apart from the third pattern in the second direction;
generating the second light incident into the substrate by changing the light path of the first light based on the first vertical pattern area graphic data and the second vertical pattern area graphic data; and
forming a second pattern array on the substrate that includes the third and fourth patterns spaced apart in the second direction by exposing the substrate with the second light in the first direction.

10. The method of claim 9, wherein
generating the first vertical pattern area graphic data and the second vertical pattern area graphic data comprises dividing a graphic data corresponding to the second pattern array.

11. A digital exposure apparatus comprising:
a stage configured to receive a substrate;
and
an exposure part configured to generate a second light comprising plural light paths based on a first pattern area graphic data corresponding to a first pattern and a second pattern area graphic data corresponding to a second pattern spaced apart from the first pattern in a first direction in a plan view, and to use the second light to expose a first exposure area of the substrate based on the first pattern area graphic data and a second exposure area of the substrate based on the second pattern area graphic data in a second direction perpendicular to the first direction.

12. The digital exposure apparatus of claim 11, wherein
the exposure part comprises a light source part configured to generate a first light, and a first digital micro mirror device comprising a plurality of digital micro mirrors configured to convert the first light into the second light.

13. The digital exposure apparatus of claim 11, wherein a border between the first exposure area and the second exposure area is spaced apart from patterns of the first pattern area graphic data and patterns of the second pattern area graphic data.

14. The digital exposure apparatus of claim 11, wherein the second exposure area partially overlaps the first exposure area.

15. The digital exposure apparatus of claim 12, wherein the exposure part further comprises a second digital micro mirror device spaced apart from the first digital micro mirror device that comprises a plurality of digital micro mirrors configured to convert the first light into the second light.

16. The digital exposure apparatus of claim 15, wherein
the first digital micro mirror device is configured to expose the first exposure area, and
the second digital micro mirror device is configured to expose the second exposure area.

17. The digital exposure apparatus of claim 11, wherein the first pattern area graphic data and the second pattern area graphic data are generated by dividing a graphic data corresponding to a first pattern array comprising the first and second patterns.

18. The digital exposure apparatus of claim 17, wherein the graphic data is divided based on a pixel unit.

19. A method for digitally exposing a substrate, comprising the steps of:
generating a first horizontal pattern area graphic data and a second horizontal pattern area graphic data, wherein the first horizontal pattern area graphic data corresponds to a first pattern, and the second horizontal pattern area graphic data corresponds to a second pattern; and
forming the first pattern in a first horizontal exposure area of the substrate from the first horizontal pattern area graphic data and the second pattern in a second horizontal exposure area of the substrate spaced apart in a first direction from the first pattern from the second horizontal pattern area graphic data by exposing the substrate to a second light in a second direction perpendicular to the first direction in a plan view.

20. The method of claim 19, further comprising:
generating the second light by changing a light path of a first light based on the first horizontal pattern area graphic data and the second horizontal pattern area graphic data,
wherein the light path of the first light is changed by a digital micro mirror part configured to expose the first horizontal exposure area based on the first horizontal pattern area graphic data, and to expose the second horizontal exposure area based on the second horizontal pattern area graphic data,
the digital micro mirror part comprises a first digital micro mirror device and a second digital micro mirror device spaced apart from the first digital micro mirror device,
the first horizontal exposure area is exposed with the first digital micro mirror device; and
the second horizontal exposure area is exposed with the second digital micro mirror device.
